(19) United States
(12) Patent Application Publication
(10) Pub. No.: US 2018/0182727 A1
(43) Pub. Date: Jun. 28, 2018

(54) EMBEDDED SILICON SUBSTRATE FAN-OUT TYPE PACKAGING STRUCTURE AND MANUFACTURING METHOD THEREFOR

(71) Applicant: HUATIAN TECHNOLOGY (KUNSHAN) ELECTRONICS CO., LTD., Kunshan (CN)

(72) Inventor: Daquan YU, Kunshan (CN)

(21) Appl. No.: 15/893,691

(22) Filed: Feb. 11, 2018

Related U.S. Application Data
(63) Continuation of application No. PCT/CN2016/085925, filed on Jun. 15, 2016.

(30) Foreign Application Priority Data
Aug. 11, 2015 (CN) 201510486674.1

(51) Int. Cl. H01L 23/00; H01L 21/56; H01L 23/06; H01L 23/18; H01L 23/488

(52) U.S. Cl. CPC H01L 24/19; H01L 21/56; H01L 23/06; H01L 23/18; H01L 2924/3511; H01L 24/20; H01L 2924/157; H01L 2224/04105; H01L 23/488

(57) ABSTRACT

An embedded silicon substrate fan-out type packaging structure comprises: a silicon substrate having a first surface and a second surface opposite thereto, at least one groove extending towards the second surface being formed on the first surface; at least one chip placed in the groove, a pad surface of the chip being opposite to a bottom of the groove; a second dielectric layer formed on the chip and the first surface; at least one layer of metal wiring connected to pads of the chip, formed on the second dielectric layer; under bump metal layers for planting solder balls, formed on an outermost layer of metal wiring; and solder balls or bumps planted on the under bump metal layers, wherein at least one solder ball or bump and at least one under bump metal layer corresponding thereto are on the first surface of the silicon substrate.

### CROSS-REFERENCE TO RELATED APPLICATIONS

The present application is a continuation of International Patent Application No. PCT/CN2016/085925 filed on Jun. 15, 2016, which claims priority to Chinese Patent Application No. 201510486674.1, filed on Aug. 11, 2015, all contents of which are incorporated by reference herein.

### TECHNICAL FIELD

The present invention relates to the field of semiconductor packaging technology, particularly to an embedded silicon substrate fan-out type packaging structure and a manufacturing method therefor.

### BACKGROUND

As a chip becomes smaller and smaller, and the number of I/Os is more and more, chip level package can't meet I/O fan-out requirements. Fan-out Wafer Level Package (FOWLP) technology is a supplement to wafer level chip size packaging technology. With leading out I/O ports of a chip by the method of reconfiguring wafer and forming solder balls or bumps terminal array in the reconfigured encapsulation, FOWLP may replace traditional Wire Bonding Ball Grid Array (WBBGA) package or Flip Chip Ball Grid Array (FCBGA) package (<500 I/Os) in a certain range, thus it is especially suitable for the booming portable consumer electronics field.

As FOWLP technology matures gradually and costs continue to drop, along with continuous improvement of chip technology (baseband chips and mobile terminal application processor chips have entered 28 nm mass production), there may be an explosive growth in FOWLP. In order to achieve cost reduction, it will develop towards Panel Size Fan-out WLP (PWLP), and may be realized by using a packaging substrate process.

### SUMMARY

Embodiments of the present invention are directed toward an embedded silicon substrate fan-out type packaging structure and a manufacturing method therefor, which may reduce the difficulty of the process, thus the cost is significantly reduced and the yield is improved.

An embedded silicon substrate fan-out type packaging structure according to the embodiments of the present invention comprises: a silicon substrate having a first surface and a second surface opposite thereto, at least one groove extending towards the second surface being formed on the first surface; at least one chip placed in the groove, a pad surface of the chip being opposite to a bottom of the groove; a second dielectric layer formed on the chip and the first surface; at least one layer of metal wiring connected to pads of the chip, formed on the second dielectric layer; under bump metal layers for planting solder balls, formed on the outermost layer of metal wiring; and solder balls or bumps planted on the under bump metal layers, wherein at least one solder ball or bump and at least one under bump metal layer corresponding thereto are on the first surface of the silicon substrate.

In an embodiment of the present invention, there are gaps between sides of the chip and side walls of the groove, the packaging structure further comprises a first dielectric layer and a passivation layer, wherein the first dielectric layer is filled in the gaps, and the passivation layer which covers the outermost layer of metal wiring is provided with openings corresponding to the under bump metal layers.

In an embodiment of the present invention, the first dielectric layer is made of a polymer adhesive, and the second dielectric layer is made of a same kind of polymer adhesive as the first dielectric layer.

In an embodiment of the present invention, the distance between the bottom of the groove and the second surface of the silicon substrate is greater than 1 micron.

In an embodiment of the present invention, side walls of the groove are perpendicular or nearly perpendicular to the bottom of the groove, and the distance between side walls of the groove and the chip is greater than 1 micron.

In an embodiment of the present invention, the pad surface of the chip is close to the first surface of the silicon substrate, and the height difference between the pad surface of the chip and the first surface of the silicon substrate is less than 50 microns.

In an embodiment of the present invention, the packaging structure further comprises an adhesive layer attached between a bottom of the chip and the bottom of the groove.

In an embodiment of the present invention, the adhesive layer has a thickness of less than 50 microns and greater than 1 micron and is a non-conductive polymer adhesive or film.

In an embodiment of the present invention, the metal wiring is made of copper or aluminum, and the under bump metal layers are made of one of Ni/Au, Cr/W/Cu, Ti/W/Cu/Ni/Au and Ti/Cu.

In an embodiment of the present invention, the solder balls or bumps are copper pillar solder balls or solder bumps.

A manufacturing method for an embedded silicon substrate fan-out type packaging structure according to the embodiments of the present invention comprises: providing a silicon substrate wafer having a first surface and a second surface opposite thereto, and etching the first surface of the silicon substrate wafer to form at least one groove; placing at least one chip to be packaged in the groove, with a pad surface of the chip facing upwards; forming an insulating second dielectric layer on the pad surface of the chip and the first surface of the silicon substrate; opening the second dielectric layer above pads of the chip, and making metal wiring connected to the pads of the chip on the second dielectric layer; preparing under bump metal layers on the outermost layer of metal wiring; and performing bumps preparation or solder balls plantation on the under bump metal layers, and finally slicing the silicon substrate wafer embedding the chip to form an embedded silicon substrate fan-out type packaging structure.

In an embodiment of the present invention, before and after performing the bumps preparation or the solder balls plantation, the manufacturing method further comprises: thinning the second surface of the silicon substrate wafer so that the thickness between a bottom of the groove and the second surface of the silicon substrate is greater than 1 micron.

In an embodiment of the present invention, placing at least one chip to be packaged in the groove comprises: thinning the chip wafer to be packaged into a set thickness, attaching an adhesive on a non-pad surface of the chip wafer, slicing to form a single chip, and placing the single chip attached with the adhesive in the groove of the silicon substrate using a pick-up tool.

In an embodiment of the present invention, there are gaps between the chip and side walls of the groove, and after placing at least one chip to be packaged in the groove, the manufacturing method further comprises: filling an adhesive in the gaps between the side walls of the groove and the chip, and curing the adhesive to form an insulating first dielectric layer; and preparing under bump metal layers on the outermost layer of metal wiring comprises: forming a passivation layer on the metal wiring, opening the passivation layer on the metal wiring where the solder balls need to be planted, and preparing the required under bump metal layers on exposed metal wiring.

In an embodiment of the present invention, filling the adhesive in the gaps between the side walls of the groove and the chip is implemented in a vacuum environment.

In an embodiment of the present invention, the second dielectric layer and the passivation layer are made of a photolithographic material, and the adhesive filled in the gaps is a polymer adhesive.

The embedded silicon substrate fan-out type packaging structure and the manufacturing method therefor according to the embodiments of the present invention use a silicon substrate instead of a molding compound as a fan-out substrate, which may make fine wiring by making full use of the advantages of the silicon substrate, and may accurately etch holes, grooves and other structures by using the mature silicon etching process. The chip is embedded in the groove of the silicon substrate, and partial solder balls are fanned out to the surface of the silicon substrate, thus the reliability of the package can be improved, the process is simple and low in cost. Since the silicon substrate has a good heat dissipation, the improvement of the packaging heat dissipation is facilitated. As the silicon substrate wafer has a small warping degree, small wiring line widths may be acquired and it is suitable for high-density package. In the process, the wafer plastic molding and the debonding process may be eliminated in the embodiments of the present invention, which reduces the difficulty of the process, thus the cost is significantly reduced and the yield is improved.

### BRIEF DESCRIPTION OF DRAWINGS

FIG. 1 is a schematic diagram illustrating a fan-out type packaging structure in which one chip is embedded in one groove according to an embodiment of the present invention.

FIG. 2 is a schematic diagram illustrating a fan-out type packaging structure in which two chips are embedded in one groove according to another embodiment of the present invention.

FIG. 3 is a schematic diagram illustrating a fan-out type packaging structure in which two different chips are embedded in two grooves respectively according to still another embodiment of the present invention.

### DETAILED DESCRIPTION

In the following detailed description, embodiments will be described with reference to the accompanying drawings. However, the present invention may be embodied in various different forms, and should not be construed as being limited only to the illustrated embodiments. Rather, these embodiments are provided as examples, simply by way of illustrating the concept of the present invention to those skilled in the art. Accordingly, processes, elements, and techniques that should be apparent to those of ordinary skill in the art are not described herein.

At present, the standard eWLB process flow is as follows: firstly, a film is attached to a slide, and then a chip is placed on the film with the pad surface of the chip facing down; the chip is embedded into a molding compound using a wafer level injection molding process; the molding compound is cured, and the slide is removed. Then a wafer level process is carried out on the molding compound wafer embedded with the chip. Passivation, metal rewiring, under bump metal layers preparation and balls plantation are carried out on the side of the chip where the pads are exposed, and finally the package is finished by slicing.

For example, Patent Publications US20080308917 and US20150003000 use polymers or other plastic sealing materials to coat a number of chips, so the chips are embedded in them, and then a wafer level process is carried out. The method has the following main problems. Firstly, there is a problem of warping of the polymer adhesive wafer. Although using a silicon or glass slide may reduce warpage, it will result in a complex process of temporary bonding and debonding. If a new type of low warpage molding compound is researched and developed, the material cost is high. Secondly, for a 10×10 mm to 12×12 mm fan-out encapsulation, the reliability of board level has great challenges, especially for the tests related to temperature cycling. For eWLB products, an underfill adhesive is needed to improve the reliability after board level connection. Thirdly, the use of the polymer adhesive wafer has a great influence on yield. Chip offset is a major technological obstacle in the process of injection molding and molding compound curing. Another key point is the choice of rewiring dielectric materials. Since a reconfigured wafer needs to adapt to the rewiring process, and the standard wafer level media can't be directly applied.

Patent Publication CN104037133A discloses a fan-out packaging structure. The structure is grooved on a silicon carrier board, a chip is inverted at the bottom of the groove, and the electrical property of the chip pads is led to the surface of the silicon carrier board through circuits. The groove is filled with a plastic sealing material, and the circuit is derived electrically by a rewiring metal made on the surface of the plastic sealing material. Thus the structure and process of the fan-out packaging structure are very complex, and the cost is high.

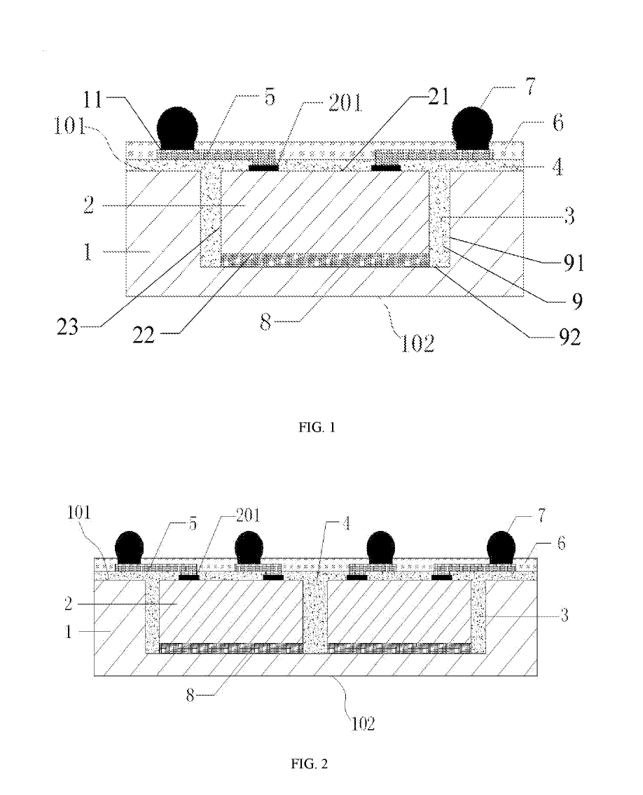

FIG. 1 is a schematic diagram illustrating a silicon substrate fan-out type packaging structure in which one chip is embedded in one groove according to an embodiment of the present invention. As shown in FIG. 1, the packaging structure comprises a silicon substrate 1 which has a first surface 101 and a second surface 102 opposite thereto. A groove 9 extending towards the second surface 102 is formed on the first surface 101. A chip 2 is placed in the groove 9, and a pad surface 21 of the chip 2 faces upwards. The chip 2 and the first surface 101 are paved with an insulating second dielectric layer 4. At least one layer of metal wiring 5 connected to pads 201 of the chip 2 is formed on the second dielectric layer 4. Under bump metal layers 11 for planting solder balls are formed on the outermost layer of metal wiring 5, and solder balls or bumps 7 are planted on the under bump metal layers 11. At least one solder ball or bump 7 and at least one under bump metal layer 11 corresponding thereto are on the first surface 101.

In an embodiment of the present invention, the outermost layer of metal wiring 5 is covered with a passivation layer 6. The passivation layer 6 is provided with openings (not shown) corresponding to the under bump metal layers 11, and the solder balls or bumps 7 are planted in the openings.

Preferably, there are gaps between sides 23 of the chip 2 and side walls 91 of the groove 9. A first dielectric layer 3 is filled in the gaps, which may prevent the offset of the chip 2 in the groove 9.

In an embodiment of the present invention, the first dielectric layer 3 is made of a polymer adhesive, and the vacuum coating is applied to fill the polymer adhesive in the gaps of the groove 9 to fix the chip 2 and ensure the insulation performance.

Preferably, the second dielectric layer 4 is made of a same kind of polymer adhesive as the first dielectric layer 3, which may improve the reliability of the package.

Preferably, the distance between the side walls 91 of the groove 9 and the chip 2 is greater than 1 micron, so that the chip 2 can be conveniently placed in the bottom 92 of the groove 9.

Preferably, the groove 9 is a straight groove or a inclined groove with an angle between the side walls 91 and the bottom 92 of 80° to 120°, that is, the side walls 91 of the groove 9 are perpendicular or nearly perpendicular to the bottom 92 of the groove 9. The groove 9 shown in FIG. 1 is a straight groove, however, those skilled in the art may understand it is not limited in the present invention.

Preferably, the distance between the bottom 92 of the groove 9 and the second surface 102 of the silicon substrate 1 is greater than 1 micron to facilitate the support of the silicon substrate 1 to the chip 2.

In an embodiment of the present invention, the pad surface 21 of the chip 2 is close to the first surface 101 of the silicon substrate 1. Preferably, the height difference between the pad surface 21 of the chip 2 and the first surface 101 of the silicon substrate 1 is less than 50 microns to ensure the uniformity of the material on the surface of the package.

In an embodiment of the present invention, an adhesive layer 8 is attached between the bottom (non-pad surface) 22 of the chip 2 and the bottom 92 of the groove 9, and the chip 2 is bonded to the bottom 92 of the groove 9 through the adhesive layer 8, so that the chip 2 may be fixed well and the chip offset can be avoided.

In an embodiment of the present invention, the adhesive layer 8 has a thickness of less than 50 microns and greater than 1 micron. Preferably, the adhesive layer 8 is a non-conductive polymer adhesive or film, bonding the chip 2 and the bottom 92 of the groove 9, which ensures that the position of the chip 2 does not shift in the subsequent process, so as to get good alignment accuracy and fine rewiring lines. The polymer adhesive may be prepared by coating on the back of the chip wafer, and the film may be prepared by pressing film on the back of the chip wafer.

Preferably, the metal wiring 5 is made of copper or aluminum.

Preferably, the solder balls or bumps 7 are copper pillar solder balls or solder bumps.

Preferably, the under bump metal layers 11 are made of one of Ni/Au, Cr/W/Cu, Ti/W/Cu/Ni/Au and Ti/Cu, which is not shown in the diagram. The Ni/Au means a layer of metal nickel is formed firstly and then a layer of metal gold is formed on the metal nickel. Similarly, the Cr/W/Cu means three layers of metal chromium, metal tungsten and metal copper are formed sequentially, the Ti/W/Cu/Ni/Au means five layers of metal titanium, metal tungsten, metal copper, metal nickel and metal gold are formed sequentially, and the Ti/Cu means two layers of metal titanium and metal copper are formed sequentially.

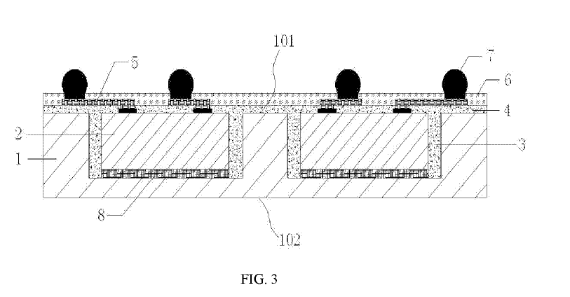

FIG. 2 is a schematic diagram illustrating a fan-out type packaging structure in which two chips are embedded in one groove according to another embodiment of the present invention. As shown in FIG. 2, the packaging structure according the embodiment of the present invention includes all the technical features of the embodiment shown in FIG. 1, and the difference is that the groove 9 on the first surface 101 of the silicon substrate 1 is embedded with two chips 2. The sizes and functions of the two chips 2 may be the same or different. The embodiment may extend the functionality of the package.

FIG. 3 is a schematic diagram illustrating a fan-out type packaging structure in which two different chips are embedded in two grooves respectively according to still another an embodiment of the present invention. As shown in FIG. 3, the packaging structure according the embodiment of the present invention includes all the technical features of the embodiment shown in FIG. 1, and the difference is that, the first surface 101 of the silicon substrate 1 is formed with two grooves 9, and each groove 9 is embedded with one chip 2 respectively. The sizes and functions of the two chips 2 may be the same or different. The embodiment may extend the functionality of the package and reduce the signal interference between the two chips.

The embodiments of the present invention also provide a manufacturing method for the embedded silicon substrate fan-out type packaging structure, and the manufacturing method includes:

Step 1: providing a silicon substrate wafer having a first surface and a second surface opposite thereto, and etching the first surface of the silicon substrate wafer to form at least one groove having a set shape and depth;

Step 2: placing at least one chip to be packaged in the groove, with a pad surface of the chip facing upwards;

Step 3: forming an insulating second dielectric layer on the pad surface of the chip and the first surface of the silicon substrate;

Step 4: opening the second dielectric layer above pads of the chip, and making metal wiring connected to the pads of the chip on the second dielectric layer;

Step 5: preparing required under bump metal layers on the outermost layer of metal wiring;

Step 6: performing bumps preparation or solder balls plantation on the under bump metal layers, and finally slicing the silicon substrate wafer embedding the chip to form an embedded silicon substrate fan-out type packaging structure.

Preferably, placing at least one chip to be packaged in the groove in Step 2 specifically comprises: thinning the chip wafer to be packaged into a set thickness, attaching an adhesive on a non-pad surface of the chip wafer, slicing to form a single chip, and placing the single chip attached with the adhesive in the groove of the silicon substrate using a pick-up tool.

In an embodiment of the present invention, there are gaps between the chip and side walls of the groove, and after Step 2, the manufacturing method further comprises: filling an adhesive in the gaps between the side walls of the groove and the chip, and curing the adhesive to form an insulating first dielectric layer.

Preferably, filling the adhesive in the gaps between the side walls of the groove and the chip is implemented in a vacuum environment, which may reduce the bubbles and ensure the gap filling effect.

Preferably, the adhesive filled in the gaps is a polymer adhesive. More preferably, the second dielectric layer is made of the same polymer adhesive as the first dielectric layer, so as to improve the reliability of the package.

In an embodiment of the present invention, preparing required under bump metal layers on the outermost layer of metal wiring (Step 5) comprises: forming a passivation layer on the metal wiring, opening the passivation layer on the metal wiring where solder balls need to be planted, and preparing the required under bump metal layers on the exposed metal wiring.

Preferably, the second dielectric layer and the passivation layer are made of a photolithographic material, so as to form openings by using a photolithography process to expose the pads of the chip and connect the metal wring to the pads.

In an embodiment of the present invention, before and after performing the bumps preparation or the solder balls plantation, the manufacturing method further comprises: thinning the second surface of the silicon substrate wafer.

Preferably, the thickness between the bottom of the groove and the second surface of the silicon substrate is greater than 1 micron after the second surface is thinned, which may facilitate the support of the silicon substrate to the chip.

The embedded silicon substrate fan-out type packaging structure and the manufacturing method therefor according to the embodiments of the present invention use a silicon substrate instead of a molding compound as a fan-out substrate, which may make fine wiring by making full use of the advantages of the silicon substrate, and may accurately etch holes, grooves and other structures by using the mature silicon etching process. Chips are embedded in the grooves of the silicon substrate, bonded and fixed to the bottom of the grooves through the adhesive layers, which avoids the chips offset. I/O ports are fanned out to the surface of the chips and the silicon substrate through rewiring, the reliability of the package can be improved, the process is simple and low in cost. Since the silicon substrate has a good heat dissipation, the improvement of the packaging heat dissipation is facilitated. As the silicon substrate wafer has a small warping degree, it may get small wiring line widths and is suitable for high-density package. In the process, the wafer plastic molding and the debonding process may be eliminated in the present invention, which reduces the difficulty of the process, thus the cost is significantly reduced and the yield is improved. The chip offset may be prevented by filling the gaps between the chips and the side walls of the grooves with the polymer adhesive. Preferably, the reliability of the package may be improved by forming the first dielectric layer and the second dielectric layer with the same polymer adhesive.

While the present disclosure has been described with reference to exemplary embodiments, it will be apparent to those skilled in the art that various changes and modifications may be made without departing from the spirit and scope of the present invention. Therefore, the above embodiments are provided for illustrative purposes only, and should not in any sense be interpreted as limiting the scope of the present disclosure.

What is claimed is:

1. An embedded silicon substrate fan-out type packaging structure, comprising:
a silicon substrate having a first surface and a second surface opposite thereto, at least one groove extending towards the second surface being formed on the first surface;
at least one chip placed in the groove, a pad surface of the chip being opposite to a bottom of the groove;
a second dielectric layer formed on the chip and the first surface;
at least one layer of metal wiring connected to pads of the chip, formed on the second dielectric layer;
under bump metal layers for planting solder balls, formed on an outermost layer of metal wiring; and
solder balls or bumps planted on the under bump metal layers, wherein at least one solder ball or bump and at least one under bump metal layer corresponding thereto are on the first surface of the silicon substrate.

2. The packaging structure according to claim 1, wherein there are gaps between sides of the chip and side walls of the groove, the packaging structure further comprises a first dielectric layer and a passivation layer, wherein the first dielectric layer is filled in the gaps, and the passivation layer which covers the outermost layer of metal wiring is provided with openings corresponding to the under bump metal layers.

3. The packaging structure according to claim 2, wherein the first dielectric layer is made of a polymer adhesive.

4. The packaging structure according to claim 3, wherein the second dielectric layer is made of a same kind of polymer adhesive as the first dielectric layer.

5. The packaging structure according to claim 1, wherein a distance between the bottom of the groove and the second surface of the silicon substrate is greater than 1 micron.

6. The packaging structure according to claim 1, wherein side walls of the groove are perpendicular or nearly perpendicular to the bottom of the groove.

7. The packaging structure according to claim 6, wherein a distance between the side walls of the groove and the chip is greater than 1 micron.

8. The packaging structure according to claim 1, wherein the pad surface of the chip is close to the first surface of the silicon substrate.

9. The packaging structure according to claim 8, wherein a height difference between the pad surface of the chip and the first surface of the silicon substrate is less than 50 microns.

10. The packaging structure according to claim 1, further comprising an adhesive layer attached between a bottom of the chip and the bottom of the groove.

11. The packaging structure according to claim 10, wherein the adhesive layer has a thickness of less than 50 microns and greater than 1 micron.

12. The packaging structure according to claim 10, wherein the adhesive layer is a non-conductive polymer adhesive or film.

13. The packaging structure according to claim 1, wherein the metal wiring is made of copper or aluminum, and the under bump metal layers are made of one of Ni/Au, Cr/W/Cu, Ti/W/Cu/Ni/Au and Ti/Cu.

14. The packaging structure according to claim 1, wherein the solder balls or bumps are copper pillar solder balls or solder bumps.

15. A manufacturing method for an embedded silicon substrate fan-out type packaging structure, comprising:
providing a silicon substrate having a first surface and a second surface opposite thereto, and etching the first surface of the silicon substrate to form at least one groove;
placing at least one chip to be packaged in the groove, with a pad surface of the chip facing upwards;
forming an insulating second dielectric layer on the pad surface of the chip and the first surface of the silicon substrate;
opening the second dielectric layer above pads of the chip, and making metal wiring connected to the pads of the chip on the second dielectric layer;
preparing under bump metal layers on an outermost layer of metal wiring; and
performing bumps preparation or solder balls plantation on the under bump metal layers, and finally slicing the silicon substrate embedding the chip to form an embedded silicon substrate fan-out type packaging structure.

16. The manufacturing method according to claim 15, before and after performing bumps preparation or solder balls plantation, further comprising:
thinning the second surface of the silicon substrate so that a thickness between a bottom of the groove and the second surface of the silicon substrate is greater than 1 micron.

17. The manufacturing method according to claim 15, wherein placing at least one chip to be packaged in the groove comprises:
thinning the chip wafer to be packaged into a set thickness, attaching an adhesive on a non-pad surface of the chip wafer, slicing to form a single chip, and placing the single chip attached with the adhesive in the groove of the silicon substrate using a pick-up tool.

18. The manufacturing method according to claim 15, wherein there are gaps between the chip and side walls of the groove, and after placing at least one chip to be packaged in the groove, the manufacturing method further comprises:
filling an adhesive in the gaps between the side walls of the groove and the chip, and curing the adhesive to form an insulating first dielectric layer; and
wherein preparing under bump metal layers on an outermost layer of metal wiring comprises:
forming a passivation layer on the metal wiring, opening the passivation layer on the metal wiring where the solder balls need to be planted, and preparing the required under bump metal layers on exposed metal wiring.

19. The manufacturing method according to claim 18, wherein filling the adhesive in the gaps between the side walls of the groove and the chip is implemented in a vacuum environment.

20. The manufacturing method according to claim 18, wherein the second dielectric layer and the passivation layer are made of a photolithographic material, and the adhesive filled in the gaps is a polymer adhesive.
